(19) United States
(12) Patent Application Publication
(10) Pub. No.: US 2019/0108111 A1
(43) Pub. Date: Apr. 11, 2019

(54) BIT ERROR RATE PREDICTION

(71) Applicant: Intel Corporation, Santa Clara, CA (US)

(72) Inventors: Itamar Fredi Levin, Mazkeret Batya (IL); Tsion Vidal, City of David (IL); Sagi Zalcman, Beit Kama (IL); Adee Ofir Ran, Maayan Baruch (IL)

(73) Assignee: Intel Corporation, Santa Clara, CA (US)

(21) Appl. No.: 15/727,326

(22) Filed: Oct. 6, 2017

(51) Int. Cl. G06F 11/277; G06F 11/22; H03M 13/15; G06F 13/42

(52) U.S. Cl. CPC G06F 11/277; G06F 13/4295; H03M 13/1515; G06F 11/221

(57) ABSTRACT

An apparatus to derive a symbol error rate of an interconnect under test from a detector error rate of the interconnect, including: an error storage buffer; an input interface to communicatively couple to a serializer-deserializer at a physical level of an interconnect and to receive an input bitstream via the PHY level of the interconnect; a bitstream regenerator; a synchronization interface to receive synchronization data for the bitstream regenerator to reconstruct a clean reference bitstream; and a comparator to: compare the input bitstream to the clean reference bitstream; identify an error in the input bitstream including identifying a difference between the clean reference bitstream and the input bitstream; and store an error record in the error storage buffer, the error record including the error prepended by a plurality of clean bits to enable an analyzer to locate the error within the input data stream and construct a DER therefrom.

### FIELD OF THE SPECIFICATION

This disclosure relates in general to the field of cloud computing, and more particularly, though not exclusively, to a system and method for bit error rate prediction in a communication link.

### BACKGROUND

In some modern data centers, the function of a device or appliance may not be tied to a specific, fixed hardware configuration. Rather, processing, memory, storage, and accelerator functions may in some cases be aggregated from different locations to form a virtual “composite node.” A contemporary network may include a data center hosting a large number of generic hardware server devices, contained in a server rack (or racks) for example, and controlled by a hypervisor. Each hardware device may run one or more instances of a virtual device, such as a workload server or virtual desktop.

Communication between the physical devices hosting the virtual devices is realized through a network of links. Those links are realized through either electrical or optical media, and through end devices that convert logical data streams to physical (electrical or optical) data streams and vice versa. The end devices are termed physical layer interfaces (PLIs). They are concerned with the serialization and deserialization of the information in need of transport.

### BRIEF DESCRIPTION OF THE DRAWINGS

The present disclosure is best understood from the following detailed description when read with the accompanying FIGURES. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

FIG. 1 is a block diagram of selected components of a data center with network connectivity, according to one or more examples of the present specification.

FIG. 2 is a block diagram of a data center, according to one or more examples of the present specification.

FIG. 3 is a block diagram of components of a computing platform, according to one or more examples of the present specification.

FIG. 4 is a block diagram illustrating aspects of a system in which the teachings of the present specification may be used, according to one or more examples of the present specification.

FIG. 5 is a block diagram of a pipeline for deriving a symbol error rate (SER) with a statistically acceptable certainty from a detector error rate (DER), according to one or more examples of the present specification.

FIG. 6a is a block diagram of a test block that may be used as an embodiment, according to one or more examples of the present specification.

FIG. 6b illustrates an example entry into a first in, first out (FIFO) buffer table, according to one or more examples of the present specification.

FIG. 7 is a block diagram of a second embodiment of a test block, according to one or more examples of the present specification.

FIG. 8 is a block diagram of a third embodiment of a test block, according to one or more examples of the present specification.

FIG. 9 is a flowchart of a method of predicting a bit error rate (BER), according to one or more examples of the present specification.

FIG. 10 illustrates an experimental example of an error burst length distribution channel definition format (CDF), according to one or more examples of the present specification.

### EMBODIMENTS OF THE DISCLOSURE

The following disclosure provides many different embodiments, or examples, for implementing different features of the present disclosure. Specific examples of components and arrangements are described below to simplify the present disclosure. These are, of course, merely examples and are not intended to be limiting. Further, the present disclosure may repeat reference numerals and/or letters in the various examples. This repetition is for the purpose of simplicity and clarity and does not in itself dictate a relationship between the various embodiments and/or configurations discussed. Different embodiments may have different advantages, and no particular advantage is necessarily required of any embodiment.

A modern data center, such as a cloud data center, may employ a high-speed serial IO (HSSIO) interconnect between different hardware components. Because computing operations in such a data center may be much more distributed than they would be in a dedicated hardware appliance, the demand on interconnects continues to increase, to ensure that the interconnects do not become a bottleneck in the data center. Contemporary data center interconnects may be required to operate at speeds of 10, 40, 100, or more gigabits per second with very low latency, and with very low bit error rates (BERs) to ensure that communications are reliable and not disrupted.

To provide just one illustrative example, for a 10 Gb per second interconnect, a bit error rate of 10⁻¹² may be expected to produce approximately one error every 5 minutes. But even this low of an error rate may not be sufficient for a contemporary data center interconnect. The modern data center may demand BERs on the order of 10⁻¹⁵ or even 10⁻¹⁸. With such low BERs being expected in the data center, verification of the BER with an acceptable level of confidence becomes a nontrivial problem that is necessary to deal with.

For example, to measure an f=50 Gb per second interconnect with a BER of 10⁻¹⁵ at a 95% confidence level (CL) would require more than 40 days according to a standard confidence level computation of the form:

$$Time ( sec ) = \frac{- ln ( 1 - CL )}{f * BER}$$

Although it is very difficult to directly measure the BER of a high-speed interconnect with a very low error rate, embodiments of the present specification provide a system and method that can be used to prove the BER mathematically without measuring it directly.

This can be accomplished because the raw, uncorrected error rate coming out of the PHY of an interconnect and into the interconnect's error correction block, such as an Ethernet interconnect, may be many orders of magnitude higher than the corrected error rate of the data that are propagated up to higher levels of the interconnect stack. To convert the much higher error rate of incoming data on the interconnect to the much lower error rate expected at the higher levels of the transaction, forward error correction (FEC) or any other error correction scheme may be used. In embodiments of the present specification, FEC should be understood to relate in a nonlimiting manner to error correction, even if the error correction scheme used is different.

Note that there are existing BER extrapolation methods that attempt to predict or statistically estimate the eventual BER, based on shorter duration (i.e., short bitstream) measurements. However, one limitation of these statistical estimation methods is that they assume a certain statistical distribution of noise and interference that will remain in force over the course of a long stream of data. But where these models assume a relatively even distribution of noise and interference on the physical interconnect, they may actually assume a best case scenario that may not reflect the realities of the interconnect over the long duration of direct measurement or actual field operation.

In cases where the BER is statistically estimated, the final BER may be extrapolated from short-term measurements, while assuming a certain distribution of errors across the interface, which may be for example a Gaussian distribution. This assumption can become a limitation when the interface is not actually purely Gaussian in nature, and the result deviates from the actual field performance.

Another proxy for actual BER measurement may be for the original equipment manufacturer (OEM) and the consumer or supplier/integrator to agree on a test with an error-free period of operation. For example, the OEM and the integrator may agree that if the interconnect operates for 24 hours without encountering an error, then an acceptable error rate can be assumed. In the above case, the actual, in-field true error rate remains unknown and bounded by the error free period BER. For example, if a 50 Gbps link operates for 24 hours with no error, then its BER is better than:

$$\frac{1}{50 GBPS \times ( 24 \times 60 \times 60 sec )} = 2.314 e - 16.$$

In the case where the serializer-deserializer (SERDES) is provided as a separate IP block from the FEC, the manufacturer of the SERDES may simply demonstrate that SERDES has a particular average error rate, and the system integrator may have to assume that this average error rate will be able to yield the desired BER at the output of a FEC.

As discussed above, signal integrity, noise, and transmission power limitations exist on HSSIO systems, making it very difficult, and at least cost-ineffective, to directly produce extremely low BERs (on the order of 10⁻¹² to 10⁻¹⁸) directly at the output of the analog/mixed signal hard decision receiver. It is more practical and cost-effective to produce a BER at this level on the order of 10⁻⁴ to 10⁻⁶.

Standards bodies such as the Institute of Electrical and Electronics Engineers (IEEE) have recognized this limitation and many standards now include error correction encoding and decoding as part of the link structure, such as in SI/noise budget and performance requirements. For example, IEEE 802.3bj provides for mandatory FEC instantiation in the PHY. FEC is a well-known error correction tool, and so long as the number of errors in a codeword do not exceed a certain threshold, FEC can not only identify the errors, but can also correct the erroneous bits. For example, in a codeword of around 5000 bits, an embodiment of FEC may be able to correct somewhere on the order of 10 errors within the codeword.

Thus, as long as the errors in a transmission line are of the appropriate magnitude (e.g., on the orders of 10⁻⁴ to 10⁻⁶) and so long as they have a relatively uniform distribution throughout the data stream, FEC is able to achieve the target BER of 10⁻¹² to 10⁻¹⁸ SER at the output of the link, and provide the corrected bitstream to the next layer of the communication and/or computing system.

As discussed above, many statistical estimation techniques assume such a relatively uniform distribution of errors throughout the data stream. But this assumption actually leads to a best case assumption, which may be overly optimistic if the error distribution on the physical line is less uniform than assumed. By way of illustration, assume that a particular embodiment of a SERDES is communicatively coupled to a transmission device via a physical interconnect. The SERDES feeds into a FEC block, and so long as the SERDES maintains the target error rate of 10⁻⁴ to 10⁻⁶, the FEC can correct the bitstream to realize a target BER of between 10⁻¹² and 10⁻¹⁸. Assume by way of illustration that the SERDES has a 5000 bit codeword, and that the FEC can effectively correct a codeword so long as there are 10 or fewer errors within the codeword. This example is admittedly oversimplified, but is useful for illustration.

So long as each codeword has 10 or fewer errors, the FEC can effectively correct that codeword so that the output error rate for that codeword is SER=0. If the average number of errors per codeword is 9, and those errors are relatively uniformly distributed throughout the bitstream as may be assumed by some statistical estimation models, then an uncorrectable codeword (i.e., a codeword with more than 10 errors) is a very rare event, and the target BER of 10⁻¹² through 10⁻¹⁸ can be reached.

But if the distribution of errors is less uniform than this assumption, then the error rate at the output of the FEC can be much higher than is required.

For example, if the physical interconnect has an intermittent noise issue so that three out of four codewords has only one or two errors, but the fourth codeword has several tens of errors, the overall average of 9 errors per codeword may still be realized as in the previous example where errors were evenly distributed. But in this case, because one out of four codewords has a large number of errors, that entire codeword is lost. When the error rate exceeds the capacity of the FEC to correct the errors, the entire codeword is lost. Thus, in this rather extreme example, having a large number of errors aggregated in one in every four codewords means that the overall error rate at the output of the FEC is actually worse than the input error rate to the SERDES—in this case, the error rate would be 0.25, meaning that one in every four codewords needs to be retransmitted.

Thus, simply assuming a relatively even distribution of errors across the bitstream may not accurately predict the eventual output BER of the FEC. To accurately predict the BER at the output of the FEC, the BER of the SERDES (or the DER) cannot merely be assumed, but should be measured directly and the correct distribution calculated.

Advantageously, this not only yields a more accurate value for the BER at the output of the FEC, but also provides an opportunity to take corrective action. For example, the previous illustration contemplated a badly misconfigured physical interconnect that caused a large burst of errors in one in every four codewords. However, to achieve the target FEC, this same interconnect may simply need to be tuned to reduce the number of errors, or even to ensure that the number of errors is more evenly distributed across the bitstream.

This configuration also addresses another issue. Namely, there are some cases where the SERDES may be implemented as a separate IP block from the FEC. Thus, it may not be possible for a manufacturer of the SERDES or the FEC to know in advance the error rate that will be exchanged between the two. Thus, it may be advantageous to enable consumers of a SERDES IP block to be able to mathematically verify the overall BER that can be realized at the output of a FEC, based on the BER at the output of the SERDES IP block.

This can be the case where the SERDES is acquired from another vendor that provides technology demonstrators that do not themselves include error correction schemes such as the FEC. This may also occur where the SERDES provided is used by implementations of different standards so that the implementation of the FEC is left as an exercise for the integrator. Furthermore, internal SERDES development test chips may be produced with minimal logic content to expedite time-to-market. However, the eventual consumers of these chips may require a final verified BER at the output of the FEC with the test chip being a proof of performance. Manufacturing and taping out a full PHY test chip is costly, and may require higher certainty to justify its cost.

The present specification illustrates several embodiments of test blocks that may be used to verify a detector error rate (DER) (i.e., the BER at the output of a SERDES) and thus provide the ability to mathematically derive the symbol error rate (SER) (i.e., the BER at the output of a FEC) with an acceptable confidence level such as 95%. Advantageously, because the DER is much higher than the SER, the DER can be measured directly with a high confidence in a matter of milliseconds or seconds, while measuring the SER directly could take days, months, or years.

A system and method for bit error rate prediction will now be described with more particular reference to the attached FIGURES. It should be noted that throughout the FIGURES, certain reference numerals may be repeated to indicate that a particular device or block is wholly or substantially consistent across the FIGURES. This is not, however, intended to imply any particular relationship between the various embodiments disclosed. In certain examples, a genus of elements may be referred to by a particular reference numeral (“widget 10”), while individual species or examples of the genus may be referred to by a hyphenated numeral (“first specific widget 10-1” and “second specific widget 10-2”).

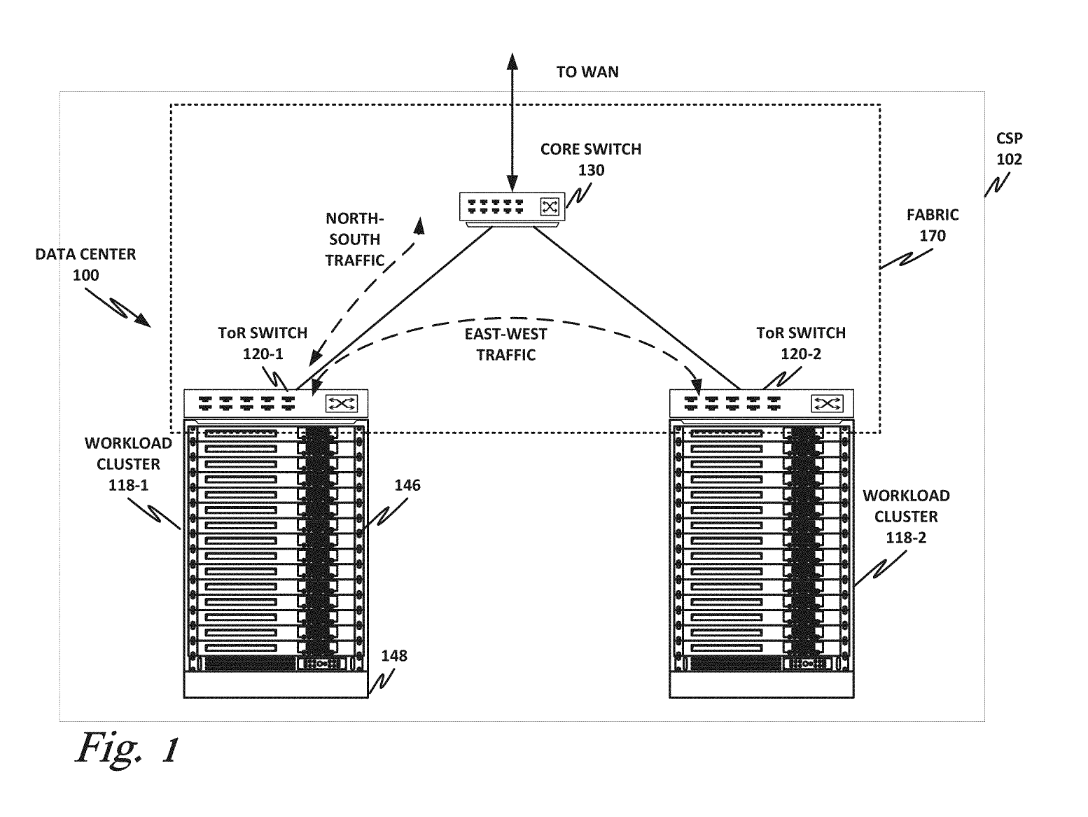

FIG. 1 is a block diagram of selected components of a data center with connectivity to network 100 of a cloud service provider (CSP) 102, according to one or more examples of the present specification. CSP 102 may be, by way of nonlimiting example, a traditional enterprise data center, an enterprise “private cloud,” or a “public cloud,” providing services such as infrastructure as a service (IaaS), platform as a service (PaaS), or software as a service (SaaS).

CSP 102 may provision some number of workload clusters 118, which may be clusters of individual servers, blade servers, rackmount servers, or any other suitable server topology. In this illustrative example, two workload clusters, 118-1 and 118-2 are shown, each providing rackmount servers 146 in a chassis 148.

In this illustration, workload clusters 118 are shown as modular workload clusters conforming to the rack unit (“U”) standard, in which a standard rack, 19 inches wide, may be built to accommodate 42 units (42U), each 1.75 inches high and approximately 36 inches deep. In this case, compute resources such as processors, memory, storage, accelerators, and switches may fit into some multiple of rack units from one to 42.

Each server 146 may host a standalone operating system and provide a server function, or servers may be virtualized, in which case they may be under the control of a virtual machine manager (VMM), hypervisor, and/or orchestrator, and may host one or more virtual machines, virtual servers, or virtual appliances. These server racks may be collocated in a single data center, or may be located in different geographic data centers. Depending on the contractual agreements, some servers 146 may be specifically dedicated to certain enterprise clients or tenants, while others may be shared.

The various devices in a data center may be connected to each other via a switching fabric 170, which may include one or more high speed routing and/or switching devices. Switching fabric 170 may provide both “north-south” traffic (e.g., traffic to and from the wide area network (WAN), such as the internet), and “east-west” traffic (e.g., traffic across the data center). Note that east-west traffic includes not only traffic between different racks, but also traffic between individual servers within a rack, and even traffic between VMs or containers on a single server (e.g., via a virtual switch (vSwitch)). Historically, north-south traffic accounted for the bulk of network traffic, but as web services become more complex and distributed, the volume of east-west traffic has risen. In many data centers, east-west traffic now accounts for the majority of traffic.

Furthermore, as the capability of each server 146 increases, traffic volume may further increase. For example, each server 146 may provide multiple processor slots, with each slot accommodating a processor having four to eight cores, along with sufficient memory for the cores. Thus, each server may host a number of VMs, each generating its own traffic, and communication between these VMs (via a vSwitch for example) constitutes a portion of data center east-west traffic.

To accommodate the large volume of traffic in a data center, a highly capable switching fabric 170 may be provided. Switching fabric 170 is illustrated in this example as a “flat” network, wherein each server 146 may have a direct connection to a top-of-rack (ToR) switch 120 (e.g., a “star” configuration), and each ToR switch 120 may couple to a core switch 130. This two-tier flat network architecture is shown only as an illustrative example. In other examples, other architectures may be used, such as three-tier star or leaf-spine (also called “fat tree” topologies) based on the “Clos” architecture, hub-and-spoke topologies, mesh topologies, ring topologies, or 3-D mesh topologies, by way of nonlimiting example. Note that the teachings of this specification also apply to cases where there is no ToR switch and different switches are instantiated within the racks themselves or at a totally different hierarchy or a separate rack. Sub-networks may also exist between the cores or server blades and these communication aggregation points

The fabric itself may be provided by any suitable interconnect. For example, each server 146 may include an Intel® Host Fabric Interface (HFI), a network interface card (NIC), integrated Ethernet controller, or other host interface. The host interface itself may couple to one or more processors via an interconnect or bus, such as PCI, PCIe, or similar, and in some cases, this interconnect bus may be considered to be part of fabric 170, especially where an integrated Ethernet controller is integrated onto the core die or SoC package.

The interconnect technology may be provided by a single interconnect or a hybrid interconnect, such as where PCIe provides on-chip or chip-to-chip communication, 1 Gb or 10 Gb copper Ethernet provides relatively short connections to a ToR switch 120 or to on-drawer sub-switches or to cores on different blade cards, and optical cabling provides relatively longer connections to core switch 130. Interconnect technologies include, by way of nonlimiting example, Intel® Omni-Path™, TrueScale™, Ultra Path Interconnect (UPI) (formerly called QPI or KTI), FibreChannel, Ethernet, FibreChannel over Ethernet (FCoE), InfiniBand, PCI, PCIe, or fiber optics by means of optical modules or silicon photonics, to name just a few. Some of these will be more suitable for certain deployments or functions than others, and selecting an appropriate fabric for the instant application is an exercise of ordinary skill.

Note however that while high-end fabrics such as Omni-Path™ are provided herein by way of illustration, more generally, fabric 170 may be any suitable interconnect or bus for the particular application. This could, in some cases, include legacy interconnects like local area networks (LANs), token ring networks, synchronous optical networks (SONET), asynchronous transfer mode (ATM) networks, wireless networks such as WiFi and Bluetooth, “plain old telephone system” (POTS) interconnects, or similar. It is also expressly anticipated that in the future, new network technologies will arise to supplement or replace some of those listed here, and any such future network topologies and technologies can be or form a part of fabric 170.

In certain embodiments, fabric 170 may provide communication services on various “layers,” as originally outlined in the OSI seven-layer network model. In contemporary practice, the OSI model is not followed strictly. In general terms, layers 1 and 2 are often called the “Ethernet” layer (though in large data centers, Ethernet has often been supplanted by newer technologies). Layers 3 and 4 are often referred to as the transmission control protocol/internet protocol (TCP/IP) layer (which may be further subdivided into TCP and IP layers). Layers 5-7 may be referred to as the “application layer.” These layer definitions are disclosed as a useful framework, but are intended to be nonlimiting.

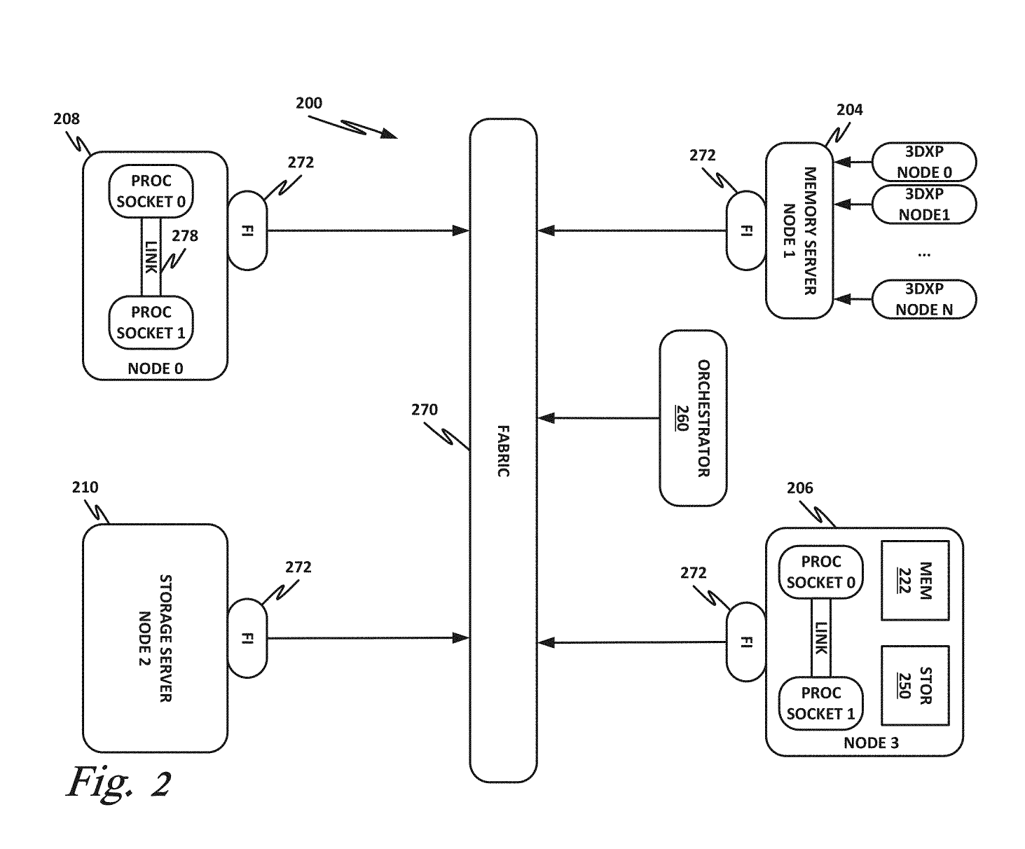

FIG. 2 is a block diagram of a data center 200 according to one or more examples of the present specification. Data center 200 may be, in various embodiments, the same as network 100 of FIG. 1, or may be a different data center. Additional views are provided in FIG. 2 to illustrate different aspects of data center 200.

In this example, a fabric 270 is provided to interconnect various aspects of data center 200. Fabric 270 may be the same as fabric 170 of FIG. 1, or may be a different fabric. As above, fabric 270 may be provided by any suitable interconnect technology. In this example, Intel® Omni-Path™ is used as an illustrative and nonlimiting example.

As illustrated, data center 200 includes a number of logic elements forming a plurality of nodes. It should be understood that each node may be provided by a physical server, a group of servers, or other hardware. Each server may be running one or more virtual machines as appropriate to its application.

Node 0 208 is a processing node including a processor socket 0 and processor socket 1. The processors may be, for example, Intel® Xeon™ processors with a plurality of cores, such as 4 or 8 cores. Node 0 208 may be configured to provide network or workload functions, such as by hosting a plurality of virtual machines or virtual appliances.

Onboard communication between processor socket 0 and processor socket 1 may be provided by an onboard link 278. This may provide a very high speed, short-length interconnect between the two processor sockets, so that virtual machines running on node 0 208 can communicate with one another at very high speeds. To facilitate this communication, a virtual switch (vSwitch) may be provisioned on node 0 208, which may be considered to be part of fabric 270.

Node 0 208 connects to fabric 270 via an HFI 272. HFI 272 may connect to an Intel® Omni-Path™ fabric. In some examples, communication with fabric 270 may be tunneled, such as by providing UPI tunneling over Omni-Path™.

Because data center 200 may provide many functions in a distributed fashion that in previous generations were provided onboard, a highly capable HFI 272 may be provided. HFI 272 may operate at speeds of multiple gigabits per second, and in some cases may be tightly coupled with node 0 208. For example, in some embodiments, the logic for HFI 272 is integrated directly with the processors on a system-on-a-chip. This provides very high speed communication between HFI 272 and the processor sockets, without the need for intermediary bus devices, which may introduce additional latency into the fabric. However, this is not to imply that embodiments where HFI 272 is provided over a traditional bus are to be excluded. Rather, it is expressly anticipated that in some examples, HFI 272 may be provided on a bus, such as a PCIe bus, which is a serialized version of PCI that provides higher speeds than traditional PCI. Throughout data center 200, various nodes may provide different types of HFIs 272, such as onboard HFIs and plug-in HFIs. It should also be noted that certain blocks in a system on a chip may be provided as intellectual property (IP) blocks that can be “dropped” into an integrated circuit as a modular unit. Thus, HFI 272 may in some cases be derived from such an IP block.

Note that in “the network is the device” fashion, node 0 208 may provide limited or no onboard memory or storage. Rather, node 0 208 may rely primarily on distributed services, such as a memory server and a networked storage server. Onboard, node 0 208 may provide only sufficient memory and storage to bootstrap the device and get it communicating with fabric 270. This kind of distributed architecture is possible because of the very high speeds of contemporary data centers, and may be advantageous because there is no need to over-provision resources for each node. Rather, a large pool of high-speed or specialized memory may be dynamically provisioned between a number of nodes, so that each node has access to a large pool of resources, but those resources do not sit idle when that particular node does not need them.

In this example, a node 1 memory server 204 and a node 2 storage server 210 provide the operational memory and storage capabilities of node 0 208. For example, memory server node 1 204 may provide remote direct memory access (RDMA), whereby node 0 208 may access memory resources on node 1 204 via fabric 270 in a DMA fashion, similar to how it would access its own onboard memory. The memory provided by memory server 204 may be traditional memory, such as double data rate type 3 (DDR3) dynamic random access memory (DRAM), which is volatile, or may be a more exotic type of memory, such as a persistent fast memory (PFM) like Intel® 3D Crosspoint™ (3DXP), which operates at DRAM-like speeds, but is nonvolatile.

Similarly, rather than providing an onboard hard disk for node 0 208, a storage server node 2 210 may be provided. Storage server 210 may provide a networked bunch of disks (NBOD), PFM, redundant array of independent disks (RAID), redundant array of independent nodes (RAIN), network attached storage (NAS), optical storage, tape drives, or other nonvolatile memory solutions.

Thus, in performing its designated function, node 0 208 may access memory from memory server 204 and store results on storage provided by storage server 210. Each of these devices couples to fabric 270 via a HFI 272, which provides fast communication that makes these technologies possible.

By way of further illustration, node 3 206 is also depicted. Node 3 206 also includes a HFI 272, along with two processor sockets internally connected by a link. However, unlike node 0 208, node 3 206 includes its own onboard memory 222 and storage 250. Thus, node 3 206 may be configured to perform its functions primarily onboard, and may not be required to rely upon memory server 204 and storage server 210. However, in appropriate circumstances, node 3 206 may supplement its own onboard memory 222 and storage 250 with distributed resources similar to node 0 208.

The basic building block of the various components disclosed herein may be referred to as “logic elements.” Logic elements may include hardware (including, for example, a software-programmable processor, an ASIC, or an FPGA), external hardware (digital, analog, or mixed-signal), software, reciprocating software, services, drivers, interfaces, components, modules, algorithms, sensors, components, firmware, microcode, programmable logic, or objects that can coordinate to achieve a logical operation. Furthermore, some logic elements are provided by a tangible, non-transitory computer-readable medium having stored thereon executable instructions for instructing a processor to perform a certain task. Such a non-transitory medium could include, for example, a hard disk, solid state memory or disk, read-only memory (ROM), persistent fast memory (PFM) (e.g., Intel® 3D Crosspoint™), external storage, redundant array of independent disks (RAID), redundant array of independent nodes (RAIN), network-attached storage (NAS), optical storage, tape drive, backup system, cloud storage, or any combination of the foregoing by way of nonlimiting example. Such a medium could also include instructions programmed into an FPGA, or encoded in hardware on an ASIC or processor.

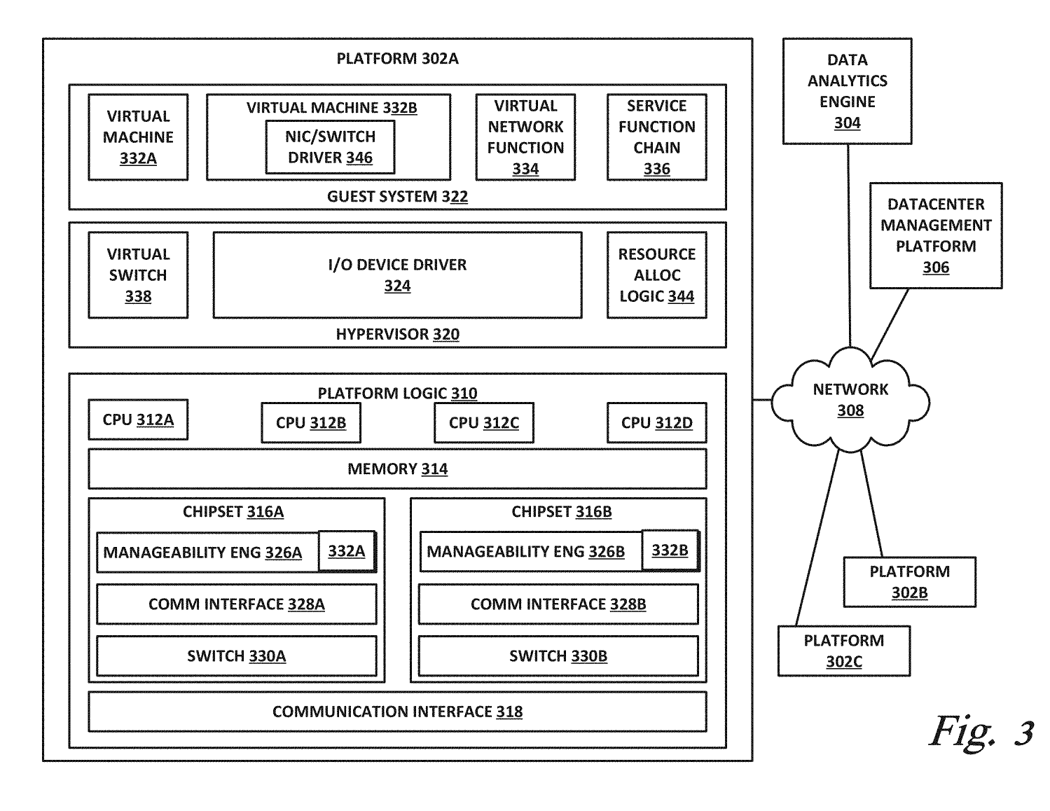

FIG. 3 illustrates a block diagram of components of a computing platform 302A according to one or more examples of the present specification. In the embodiment depicted, platforms 302A, 302B, and 302C, along with a data center management platform 306 and data analytics engine 304 are interconnected via network 308. In other embodiments, a computer system may include any suitable number of (i.e., one or more) platforms. In some embodiments (e.g., when a computer system only includes a single platform), all or a portion of the system management platform 306 may be included on a platform 302. A platform 302 may include platform logic 310 with one or more central processing units (CPUs) 312, memories 314 (which may include any number of different modules), chipsets 316, communication interfaces 318, and any other suitable hardware and/or software to execute a hypervisor 320 or other operating system capable of executing workloads associated with applications running on platform 302. In some embodiments, a platform 302 may function as a host platform for one or more guest systems 322 that invoke these applications. Platform 302A may represent any suitable computing environment, such as a high performance computing environment, a data center, a communications service provider infrastructure (e.g., one or more portions of an Evolved Packet Core), an in-memory computing environment, a computing system of a vehicle (e.g., an automobile or airplane), an Internet of Things environment, an industrial control system, other computing environment, or combination thereof.

In various embodiments of the present disclosure, accumulated stress and/or rates of stress accumulated of a plurality of hardware resources (e.g., cores and uncores) are monitored and entities (e.g., system management platform 306, hypervisor 320, or other operating system) of computer platform 302A may assign hardware resources of platform logic 310 to perform workloads in accordance with the stress information. In some embodiments, self-diagnostic capabilities may be combined with the stress monitoring to more accurately determine the health of the hardware resources. Each platform 302 may include platform logic 310. Platform logic 310 comprises, among other logic enabling the functionality of platform 302, one or more CPUs 312, memory 314, one or more chipsets 316, and communication interfaces 328. Although three platforms are illustrated, computer platform 302A may be interconnected with any suitable number of platforms. In various embodiments, a platform 302 may reside on a circuit board that is installed in a chassis, rack, or other suitable structure that comprises multiple platforms coupled together through network 308 (which may comprise, e.g., a rack or backplane switch).

CPUs 312 may each comprise any suitable number of processor cores and supporting logic (e.g., uncores). The cores may be coupled to each other, to memory 314, to at least one chipset 316, and/or to a communication interface 318, through one or more controllers residing on CPU 312 and/or chipset 316. In particular embodiments, a CPU 312 is embodied within a socket that is permanently or removably coupled to platform 302A. Although four CPUs are shown, a platform 302 may include any suitable number of CPUs.

Memory 314 may comprise any form of volatile or nonvolatile memory including, without limitation, magnetic media (e.g., one or more tape drives), optical media, random access memory (RAM), read-only memory (ROM), flash memory, removable media, or any other suitable local or remote memory component or components. Memory 314 may be used for short, medium, and/or long term storage by platform 302A. Memory 314 may store any suitable data or information utilized by platform logic 310, including software embedded in a computer readable medium, and/or encoded logic incorporated in hardware or otherwise stored (e.g., firmware). Memory 314 may store data that is used by cores of CPUs 312. In some embodiments, memory 314 may also comprise storage for instructions that may be executed by the cores of CPUs 312 or other processing elements (e.g., logic resident on chipsets 316) to provide functionality associated with the manageability engine 326 or other components of platform logic 310. A platform 302 may also include one or more chipsets 316 comprising any suitable logic to support the operation of the CPUs 312. In various embodiments, chipset 316 may reside on the same die or package as a CPU 312 or on one or more different dies or packages. Each chipset may support any suitable number of CPUs 312. A chipset 316 may also include one or more controllers to couple other components of platform logic 310 (e.g., communication interface 318 or memory 314) to one or more CPUs. In the embodiment depicted, each chipset 316 also includes a manageability engine 326. Manageability engine 326 may include any suitable logic to support the operation of chipset 316. In a particular embodiment, a manageability engine 326 (which may also be referred to as an innovation engine) is capable of collecting real-time telemetry data from the chipset 316, the CPU(s) 312 and/or memory 314 managed by the chipset 316, other components of platform logic 310, and/or various connections between components of platform logic 310. In various embodiments, the telemetry data collected includes the stress information described herein.

In various embodiments, a manageability engine 326 operates as an out-of-band asynchronous compute agent which is capable of interfacing with the various elements of platform logic 310 to collect telemetry data with no or minimal disruption to running processes on CPUs 312. For example, manageability engine 326 may comprise a dedicated processing element (e.g., a processor, controller, or other logic) on chipset 316, which provides the functionality of manageability engine 326 (e.g., by executing software instructions), thus conserving processing cycles of CPUs 312 for operations associated with the workloads performed by the platform logic 310. Moreover the dedicated logic for the manageability engine 326 may operate asynchronously with respect to the CPUs 312 and may gather at least some of the telemetry data without increasing the load on the CPUs.

A manageability engine 326 may process telemetry data it collects (specific examples of the processing of stress information will be provided herein). In various embodiments, manageability engine 326 reports the data it collects and/or the results of its processing to other elements in the computer system, such as one or more hypervisors 320 or other operating systems and/or system management software (which may run on any suitable logic such as system management platform 306). In particular embodiments, a critical event such as a core that has accumulated an excessive amount of stress may be reported prior to the normal interval for reporting telemetry data (e.g., a notification may be sent immediately upon detection).

Additionally, manageability engine 326 may include programmable code configurable to set which CPU(s) 312 a particular chipset 316 will manage and/or which telemetry data will be collected.

Chipsets 316 also each include a communication interface 328. Communication interface 328 may be used for the communication of signaling and/or data between chipset 316 and one or more IO devices, one or more networks 308, and/or one or more devices coupled to network 308 (e.g., system management platform 306). For example, communication interface 328 may be used to send and receive network traffic such as data packets. In a particular embodiment, a communication interface 328 comprises one or more physical network interface controllers (NICs), also known as network interface cards or network adapters. A NIC may include electronic circuitry to communicate using any suitable physical layer and data link layer standard such as Ethernet (e.g., as defined by a IEEE 802.3 standard), Fibre Channel, InfiniBand, Wi-Fi, or other suitable standard. A NIC may include one or more physical ports that may couple to a cable (e.g., an Ethernet cable). A NIC may enable communication between any suitable element of chipset 316 (e.g., manageability engine 326 or switch 330) and another device coupled to network 308. In various embodiments a NIC may be integrated with the chipset (i.e., may be on the same integrated circuit or circuit board as the rest of the chipset logic) or may be on a different integrated circuit or circuit board that is electromechanically coupled to the chipset. Communication interface 328 may include a physical layer interface within the communication interface, which may include error correction (e.g., forward error correction (FEC)), with a detector error rate (DER) at the output of a serializer-deserializer (SERDES), and a symbol error rate (SER) at an output of the FEC.

In particular embodiments, communication interfaces 328 may allow communication of data (e.g., between the manageability engine 326 and the data center management platform 306) associated with management and monitoring functions performed by manageability engine 326. In various embodiments, manageability engine 326 may utilize elements (e.g., one or more NICs) of communication interfaces 328 to report the telemetry data (e.g., to system management platform 306) in order to reserve usage of NICs of communication interface 318 for operations associated with workloads performed by platform logic 310.

Switches 330 may couple to various ports (e.g., provided by NICs) of communication interface 328 and may switch data between these ports and various components of chipset 316 (e.g., one or more Peripheral Component Interconnect Express (PCIe) lanes coupled to CPUs 312). Switches 330 may be a physical or virtual (i.e., software) switch.

Platform logic 310 may include an additional communication interface 318. Similar to communication interfaces 328, communication interfaces 318 may be used for the communication of signaling and/or data between platform logic 310 and one or more networks 308 and one or more devices coupled to the network 308. For example, communication interface 318 may be used to send and receive network traffic such as data packets. In a particular embodiment, communication interfaces 318 comprise one or more physical NICs. These NICs may enable communication between any suitable element of platform logic 310 (e.g., CPUs 512 or memory 514) and another device coupled to network 308 (e.g., elements of other platforms or remote computing devices coupled to network 308 through one or more networks).

Platform logic 310 may receive and perform any suitable types of workloads. A workload may include any request to utilize one or more resources of platform logic 310, such as one or more cores or associated logic. For example, a workload may comprise a request to instantiate a software component, such as an IO device driver 324 or guest system 322; a request to process a network packet received from a virtual machine 332 or device external to platform 302A (such as a network node coupled to network 308); a request to execute a process or thread associated with a guest system 322, an application running on platform 302A, a hypervisor 320 or other operating system running on platform 302A; or other suitable processing request.

A virtual machine 332 may emulate a computer system with its own dedicated hardware. A virtual machine 332 may run a guest operating system on top of the hypervisor 320. The components of platform logic 310 (e.g., CPUs 312, memory 314, chipset 316, and communication interface 318) may be virtualized such that it appears to the guest operating system that the virtual machine 332 has its own dedicated components.

A virtual machine 332 may include a virtualized NIC (vNIC), which is used by the virtual machine as its network interface. A vNIC may be assigned a media access control (MAC) address or other identifier, thus allowing multiple virtual machines 332 to be individually addressable in a network.

VNF 334 may comprise a software implementation of a functional building block with defined interfaces and behavior that can be deployed in a virtualized infrastructure. In particular embodiments, a VNF 334 may include one or more virtual machines 332 that collectively provide specific functionalities (e.g., wide area network (WAN) optimization, virtual private network (VPN) termination, firewall operations, load-balancing operations, security functions, etc.). A VNF 334 running on platform logic 310 may provide the same functionality as traditional network components implemented through dedicated hardware. For example, a VNF 334 may include components to perform any suitable NFV workloads, such as virtualized evolved packet core (vEPC) components, mobility management entities, 3rd Generation Partnership Project (3GPP) control and data plane components, etc.

SFC 336 is a group of VNFs 334 organized as a chain to perform a series of operations, such as network packet processing operations. Service function chaining may provide the ability to define an ordered list of network services (e.g. firewalls, load balancers) that are stitched together in the network to create a service chain.

A hypervisor 320 (also known as a virtual machine monitor) may comprise logic to create and run guest systems 322. The hypervisor 320 may present guest operating systems run by virtual machines with a virtual operating platform (i.e., it appears to the virtual machines that they are running on separate physical nodes when they are actually consolidated onto a single hardware platform) and manage the execution of the guest operating systems by platform logic 310. Services of hypervisor 320 may be provided by virtualizing in software or through hardware assisted resources that require minimal software intervention, or both. Multiple instances of a variety of guest operating systems may be managed by the hypervisor 320. Each platform 302 may have a separate instantiation of a hypervisor 320.

Hypervisor 320 may be a native or bare-metal hypervisor that runs directly on platform logic 310 to control the platform logic and manage the guest operating systems. Alternatively, hypervisor 320 may be a hosted hypervisor that runs on a host operating system and abstracts the guest operating systems from the host operating system. Hypervisor 320 may include a virtual switch 338 that may provide virtual switching and/or routing functions to virtual machines of guest systems 322. The virtual switch 338 may comprise a logical switching fabric that couples the vNICs of the virtual machines 332 to each other, thus creating a virtual network through which virtual machines may communicate with each other.

Virtual switch 338 may comprise a software element that is executed using components of platform logic 310. In various embodiments, hypervisor 320 may be in communication with any suitable entity (e.g., a SDN controller) which may cause hypervisor 320 to reconfigure the parameters of virtual switch 338 in response to changing conditions in platform 302 (e.g., the addition or deletion of virtual machines 332 or identification of optimizations that may be made to enhance performance of the platform).

Hypervisor 320 may also include resource allocation logic 344, which may include logic for determining allocation of platform resources based on the telemetry data (which may include stress information). Resource allocation logic 344 may also include logic for communicating with various components of platform logic 310 entities of platform 302A to implement such optimization, such as components of platform logic 310.

Any suitable logic may make one or more of these optimization decisions. For example, system management platform 306; resource allocation logic 344 of hypervisor 320 or other operating system; or other logic of computer platform 302A may be capable of making such decisions. In various embodiments, the system management platform 306 may receive telemetry data from and manage workload placement across multiple platforms 302. The system management platform 306 may communicate with hypervisors 320 (e.g., in an out-of-band manner) or other operating systems of the various platforms 302 to implement workload placements directed by the system management platform.

The elements of platform logic 310 may be coupled together in any suitable manner. For example, a bus may couple any of the components together. A bus may include any known interconnect, such as a multi-drop bus, a mesh interconnect, a ring interconnect, a point-to-point interconnect, a serial interconnect, a parallel bus, a coherent (e.g. cache coherent) bus, a layered protocol architecture, a differential bus, or a Gunning transceiver logic (GTL) bus.

Elements of the computer platform 302A may be coupled together in any suitable manner such as through one or more networks 308. A network 308 may be any suitable network or combination of one or more networks operating using one or more suitable networking protocols. A network may represent a series of nodes, points, and interconnected communication paths for receiving and transmitting packets of information that propagate through a communication system. For example, a network may include one or more firewalls, routers, switches, security appliances, antivirus servers, or other useful network devices.

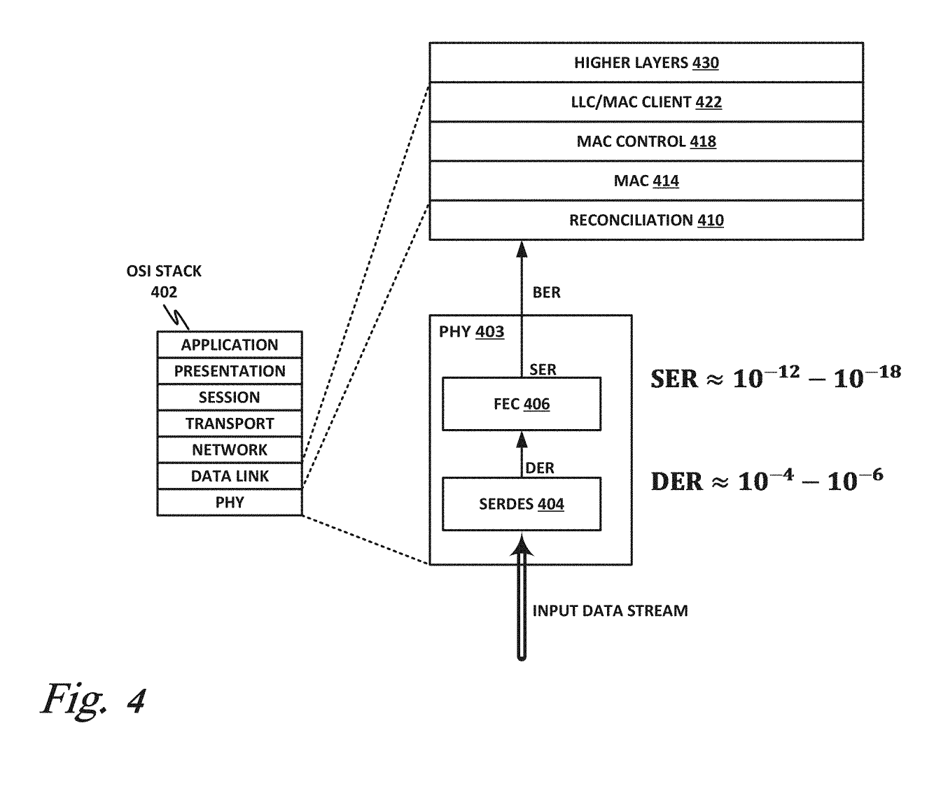

FIG. 4 is a block diagram illustrating aspects of a system in which the teachings of the present specification may be used.

Illustrated in FIG. 4 is a standard Open Systems Interconnection (OSI) stack 402, which provides the traditional and well-known seven-layer model. OSI stack 402 includes a PHY layer, data link layer, network layer, transport layer, session layer, presentation layer, and application layer.

In the teachings of the present specification, a PHY block 403 along with a reconciliation block 410, together provide the PHY layer of OSI stack 402. The data link layer includes a media access control (MAC) 414, MAC control 418, and last level cache/MAC client 422. Higher layers 430 broadly encompass a network layer, transport layer, session layer, presentation layer, and application layer.

The BER of interest throughout the teachings of the present specification may generally be at the output of PHY 403. PHY 403 receives an input data stream, and processes the data stream to provide data to reconciliation block 410 with a desired BER.

By way of nonlimiting example, PHY 403 may be an IEEE 802.3bj PHY with mandatory FEC instantiation in the PHY. FEC 406 may be configured to receive a bitstream from the lower levels of the PHY (such as the physical medium attachment (PMA), physical medium dependent (PMD), or auto-negotiation (AN) level) with a given detector error rate (DER). For example, SERDES 404 receives an input data stream via a physical interconnect which may be tuned so that DER is on the order of 10⁻⁴ to 10⁻⁶. FEC 406 is configured to correct codewords received from SERDES 404, and to yield a symbol error rate (SER) that is much less than the DER. For example, the SER may be on the order of 10⁻¹² or better.

In a well-designed HSSIO employing error correction, a DER on the order of 10⁻⁴ to 10⁻⁶ can easily be measured, even using brute force methods such as while transmitting a pseudorandom bit sequence (PRBS), or other predictable, statistically sound sequences. On the receiving side, the PRBS may be synced and compared to the input bitstream, thus enabling a direct measurement of DER.

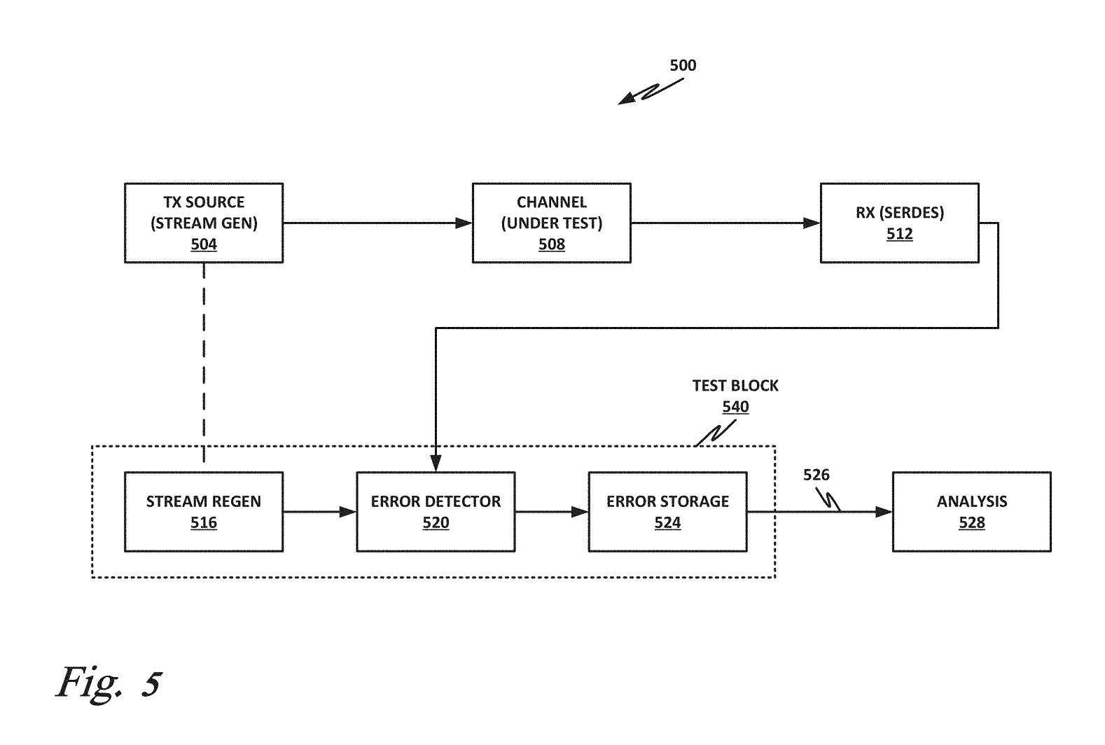

In contrast, the SER may be very difficult to measure directly because it is much lower and requires either statistical assessment or very long measurement durations. Thus, it is advantageous to provide a system and method wherein the DER is measured directly and can be used to mathematically derive the SER with an acceptable level of confidence. FIGS. 5-9 illustrate systems and methods for performing this task.

FIG. 5 is a block diagram of a pipeline 500 for deriving a SER with a statistically acceptable certainty (e.g., 95%) from a DER. In pipeline 500, a transmitter source 504 includes a stream generator. The stream generator, which includes a transmitter that converts the logical bitstream to symbols for transmission on the physical channel, provides a bitstream to a physical channel under test 508 which constitutes the board, cable, platform, or other topology under test.

A receiver 512, which may be for example a SERDES, receives symbols and detects the bitstream (i.e., it receives voltages and currents and produces the logical bitstream), via channel under test 508.

The SERDES 512 may include logic blocks to realize the teachings of this specification. In some examples, these logic blocks may be minimal with respect to the overall function of SERDES 512.

Assuming a known or predictable input data stream transmitted from source 504 to receiver 512, a clean output stream (BER=0) can be regenerated. For example, if stream generator 504 is a PRBS, then a stream regenerator 516 can use synchronization data from stream generator 504 to generate the identical stream to use as a reference stream. For example, transmitter source 504 may provide an identical seed, counter, and/or other synchronization data to stream regenerator 516, so that stream regenerator 516 can generate a clean and error-free reference stream.

In autonomous synchronization or “self-synchronization,” all information about the seed reaches the PRBS generator through the channel. Note therefore that the side channel depicted here between TX source 504 and stream regenerator 516 may be redundant in some embodiments. In some cases, stream regenerator 516 may need to be connected to the RX bit stream output. This connection is not required in every case, but in cases where stream regenerator 516 needs a snapshot of the RX bitstream to complete synchronization, it may be provided.

The synchronization may also be done autonomously by using N received bits from the bit stream as seed (for a PRBS generator with N length seed) and then running it to see if the produced bitstream equals the received bitstream. If the synchronization is performed correctly, there will be a high degree of correlation (excepting bits that were received in error) between the generated and received PRBS sequences. The synchronization process may be repeated several times until synchronization is achieved.

Error detector 520 compares the reference bitstream with the received bitstream and identifies errors, which may be recorded together with an identifier of the location of the error in the stream, and the number of bits (or frames) of data received since the beginning of the test. This provides a reliable way to identify that an error is present, and to reliably identify where in the stream the error occurred.

Detected error bursts may be recorded in error storage 524 and saved for further processing and analysis. In this way, the actual error events are captured. Error storage 512 records a few correct bits before the first error and then a block of M bits that includes the error and several bits following. If there is a burst of errors, this mechanism catches them in a single stored block.

Link 526 between error storage block 524 and analysis block 528 may be a full physical link that takes the stored errors to a different device, or it may be an internal interface that is part of the SERDES or SoC that hosts it. Link 526 could also be a complex interface like Advanced Microcontroller Bus Architecture (AMBA) High-performance bus (AHB) and may include a microprocessor that reads the error storage in parts until it has read it all or even a continuous stream of information active throughout the use of the PHY. In that case, for every block link 526 transfers, it may release some error storage memory for new errors.

Analysis block 528 may take place offline from a test block 540, and may be performed on a computing device with greater processing capabilities so that the errors stored in test block 540 can be analyzed in a timely fashion. Postprocessing of the error database, and application of mathematical analysis on the database, may be used to calculate the SER that is expected based on the DER and the actual error events encountered. This enables a bounding of the SER to be smaller than a certain target number (e.g., because a maximum SER is computed, this represents a worst-case scenario).

If a bound is insufficient and the system integrator requires an actual measurement, modifications to the bitstream and addition of more logic may be provided in the receiver. The transmitted bitstream may be encoded into actual FEC frames and the error recorder may include errors not only in the data but also in the FEC headers. Stated otherwise, not every error is equal. Some may be more serious than others depending on their positions. This embodiment constitutes less logic than the full FEC implementation, and enable a SER=X measurement, rather than a SER<=X measurement based on a provided lower bound.

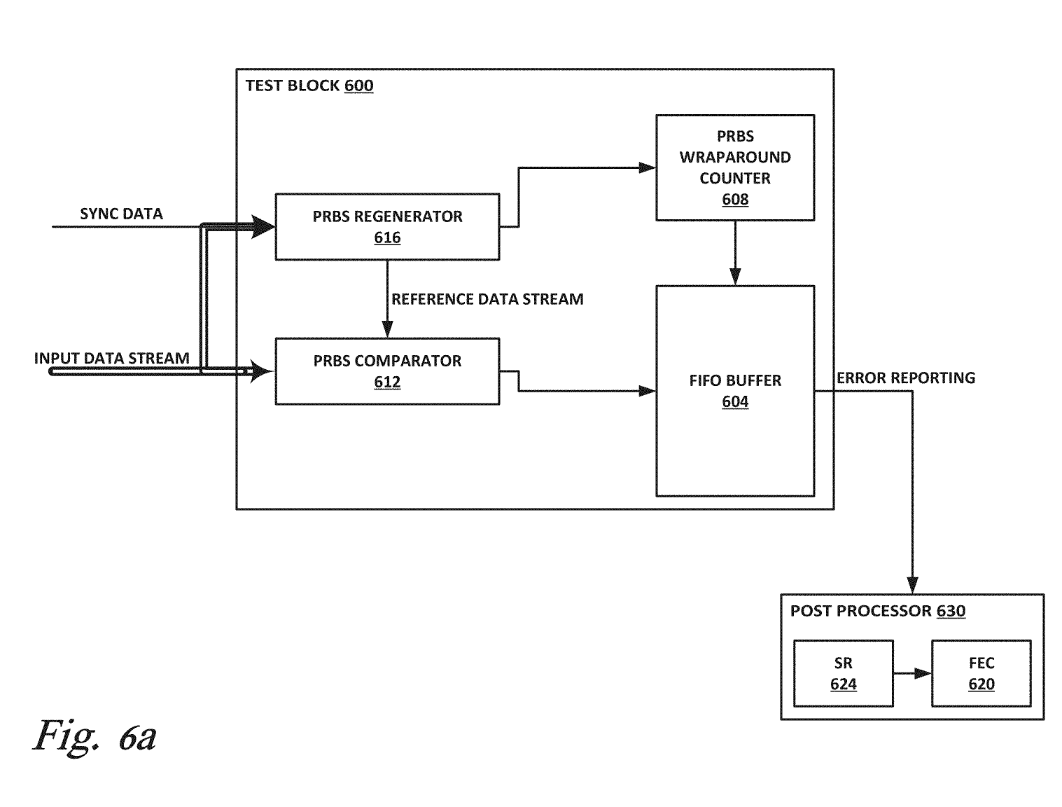

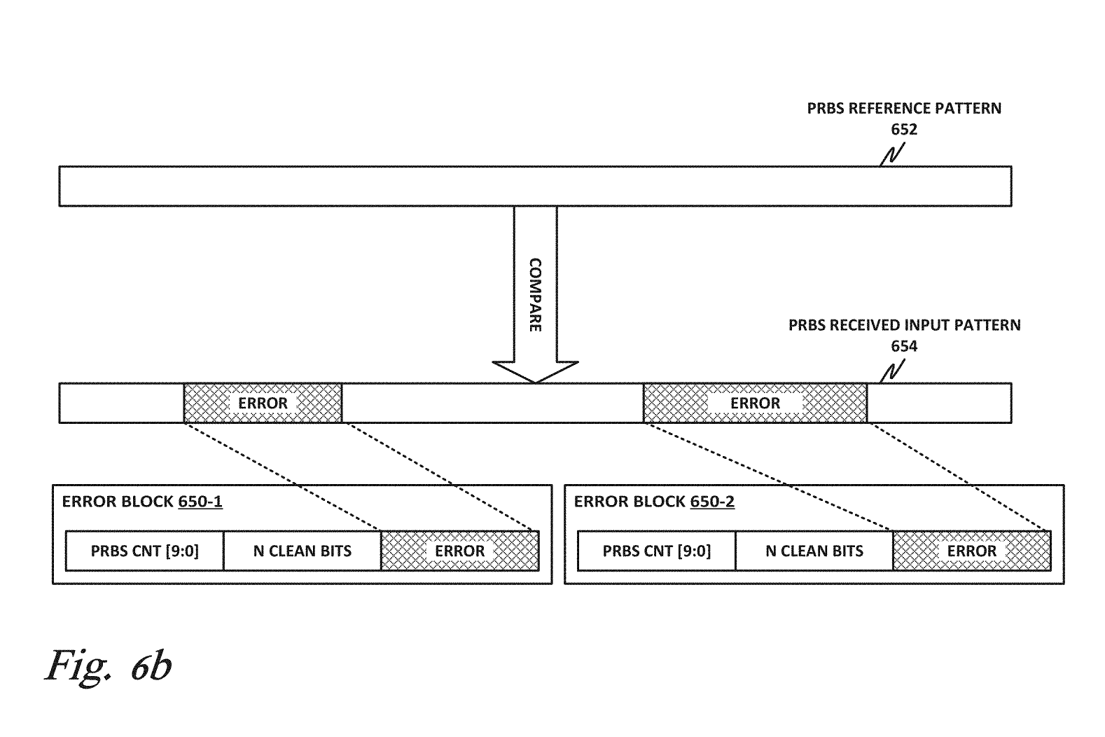

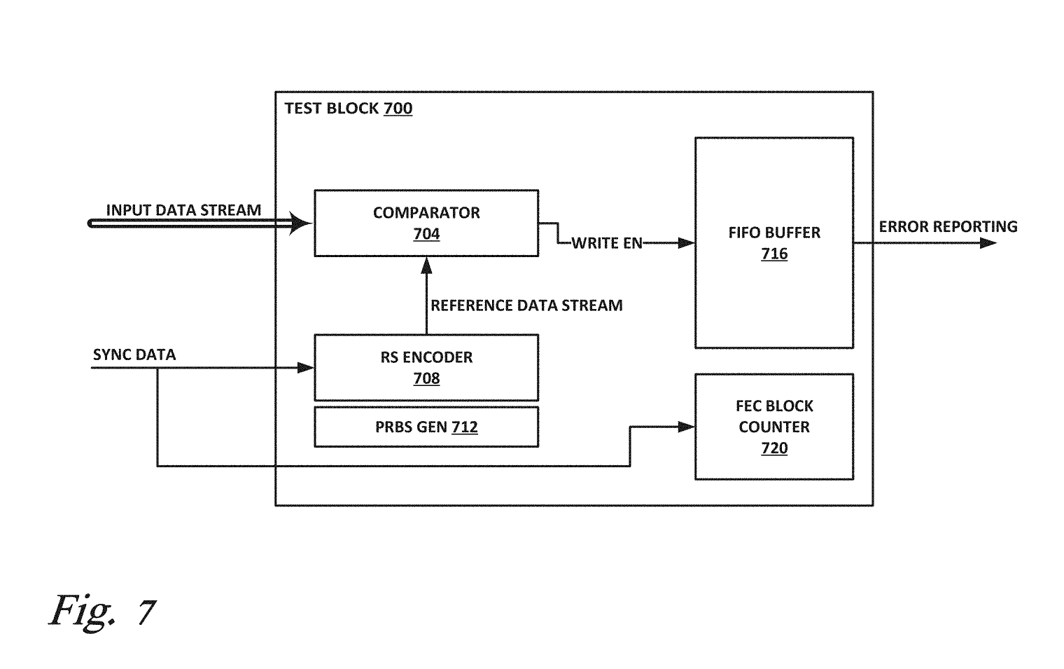

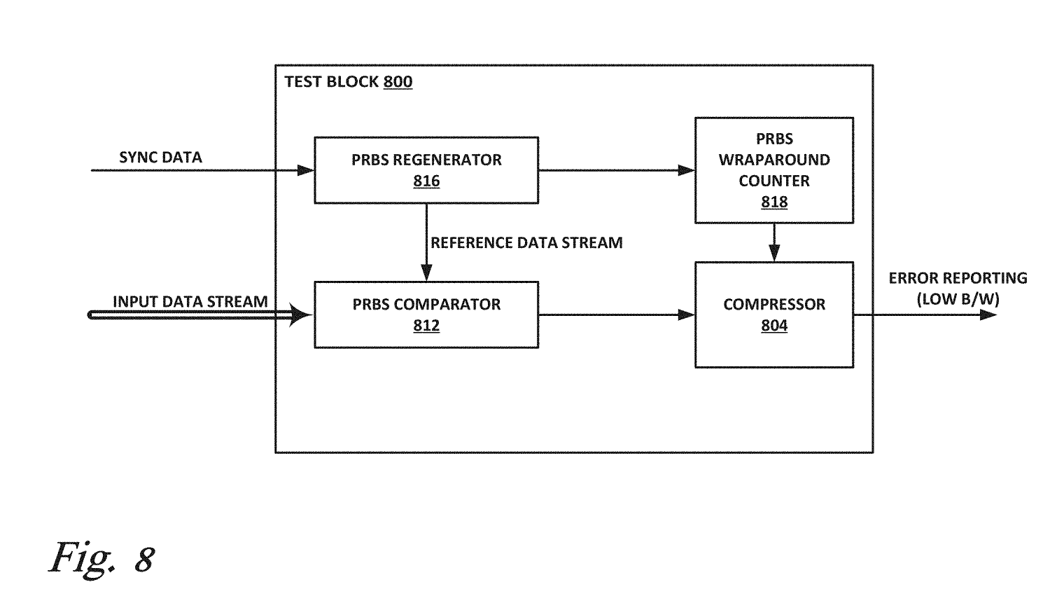

FIGS. 6a, 7, and 8 illustrate three different embodiments of a test block of the present specification that can be used to accurately compute a SER based on an actual detected and recorded DER. The embodiment of FIG. 6a is the leanest in terms of logic resources and provides only a bound on the SER (as opposed to calculating the actual SER). The embodiment of FIG. 7 includes an additional mechanism to calculate the actual SER based on the DER and error events, but requires additional logic resources in the SERDES (RX and TX). The embodiment illustrated in FIG. 8 employs compression logic to transmit the error location markers and error burst events to test bench equipment through a lower speed interconnect in a continuous or periodic manner. This allows for a more accurate, continuous, and time indefinite measurement of DER and computation of SER.

The examples illustrated in FIGS. 6a, 7, and 8 use a PRBS as an illustrative example of a predictable bitstream. It should be noted, however, that the teachings of this specification are equally applicable to any other predictable bitstream that allows direct error detection, including other codes, scrambled known data, or similar. The teachings of this specification also equally apply to such other bitstreams, including any necessary logic implementation modifications. Also note that while the teachings of this specification are disclosed with respect to FEC as an error correction scheme, the teachings apply equally well to other error correction schemes, and can be modified accordingly.

For the embodiments illustrated below, it is advantageous to record other pieces of data from the SERDES, in addition to the error event, which may be used later for postprocessing and statistical assurances that the computed BER measurements are valid. These additional data may include, by way of nonlimiting example:
Decision feedback equalizer (DFE) converged coefficients, provided that the SERDES has an equalizer.
A SERDES DER level.
An eye height at the SERDES DER level.
An eye width at the SERDES DER level.
A vertical histogram or data allowing the calculation of such.
Jitter tolerance or data allowing the calculation of such.

FIG. 6a is a block diagram of a test block 600 that may be used as an embodiment of the present specification. Note that test block 600 may correspond roughly, though not necessarily precisely, to test block 540 of FIG. 5. Thus, test block 600 does not necessarily include a SERDES on one end or a FEC on the other end, but rather receives a data stream from the SERDES as an input data stream, along with synchronization data from a stream generator such as stream generator 504 of FIG. 5. Test block 600 uses these inputs to generate a reference data stream, detect errors, and report errors out to an analysis device, such as a test bench provided with sufficient computing resources to perform the required analysis.

Assuming a known PRBS (PRBS-N) as the input data stream to test block 600, a clean output stream (with BER=0) can be generated by PRBS generator 616 using synchronization data. Because each N bit is unique in one full PRBS-N stream, reference data stream can be compared to input data stream in PRBS comparator 612. Thus, test block 600 can record the actual patterns in the RX output and place them in the expected output stream according to the N clear bits prior to the first error bit. A PRBS wraparound detector may also be used to place the error patterns in the right PRBS pattern cycle. The pre-error N bits, the error pattern, and PRBS wraparound counter 608 may all be stored in an on-die memory, such as first in, first out (FIFO) buffer 604.

An example entry into a table of FIFO buffer 604 is illustrated in FIG. 6b. PRBS input pattern 652 is compared to PRBS reference pattern 654, and one or more errors are detected. For each error block, an error block 650 may be recorded in FIFO buffer 604. An error block 650 can include, by way of nonlimiting example, a PRBS wraparound counter (which in this example is 10 bits), the N clean bits preceding the error, and the error itself. These can be provided to identify and locate the error in context so that the error can be properly analyzed by a test bench.

A post processor such as a test bench may recreate the PRBS stream, including the actual errors, and combine the errors with the regenerated stream to produce the output stream with the errors at the SERDES. A post processor 630 may include a stream reconstructor 624, and a FEC model 620. Stream reconstructor 624 may use synchronization data as with PRBS regenerator 616 to reconstruct the clean error stream, and may use reported errors from FIFO buffer 604 to insert the errors into its simulated stream. Stream reconstructor 624 may then provide the reconstructed stream to FEC model 620, and the FEC output BER (SER) can then be measured.

Based on the measured DER and error events captured in the measurement phase, post processor 630 may yield a SER or SER bound as appropriate to the embodiment. This can include, for example:

1. Measuring DER and comparing it against standard requirements for pre-error correction required DER. If DER is too high, report failure.

2. Constructing a histogram of error events and capture frequencies of single error, bursts of 2 errors, bursts of 3 errors, up to bursts of N errors. From the error burst histogram, construct the error burst probability distribution (this may be checked to ensure that it decays exponentially, or according to another distribution which is appropriate to the communication link at hand):

P(En|#En−1),P(En,En−1|#En−2), . . . , P(En,En−1,En−N−1|#En−N)

3. Examining the DFE coefficients reported by the SERDES and ensure that it decays according to a desired profile, for example, a desired profile for the FEC defined in IEEE 802.3bj as represented by the following:

W(n)≤((1−eyeopening)/2)*(⅔)n−1−sum(W(n+1),W(n+2), . . . W(n+m))

If conditions 1 through 3 are fulfilled, the SER is less than or equal to F of DER defined by the error correction scheme. If one of the three conditions is violated, then with high probability, the SER achieved at the output of the error correction scheme will not meet the specification.

In other embodiments, post processor 630 may include a calculation that, given an error pattern, determines if the FEC is able to correct the error pattern, or throw an error symbol at the output. By counting the number of error symbols from the calculation, it is possible to determine a SER bound.

Additional logic that may be required in the SERDES to implement this scheme may include, for example:
A FIFO or memory block containing DIP×5440 bits (RS block) or BER count (13 bits).
PRBS wraparound counter (16-bit), which counts how many full PRBS cycles occurred up to the error event recorded.
PRBS compare block, to compare data from SERDES and data from a PRBS regenerator and only write error bursts or bits plus sync PRBS (equals 2, for example, the key size (32 or 40) bits for PRBS 31 as an example).
On the test side, PRBS sync on header and generate the stream, not including RS overhead, and compare the reference stream to generate a stream XOR error in memory.

PRBS regenerator 616 may be synced to the incoming (TX side) PRBS at the beginning of the test by storing N bits of the sequence (assumed correct) in its generator FIFO and then computing N bits of generated PRBS to compare to the received bits as a reference bitstream. If the comparison is successful, the RX side PRBS regenerator 616 may be deemed synchronized. This synchronization may remain in force until the DER exceeds a threshold measured at the receiver, indicating a possible loss of synchronization. When a synchronization loss is measured, the measurement may be frozen and a resynchronization may be performed.

The maximal error pattern length, which is impacted by the SERDES implementation, may be predefined, or acquired through operation of the test. Conversely, a more complex recording mechanism may also be adapted to different error burst lengths dynamically.

In this scheme, there is no creation of an actual FEC or FEC parity headers. Thus, the post processor 630 may assume that the same DER exists for payload bits and header bits (which causes a determination of the FEC symbol as somewhat erroneous). Thus, the post processor assumes a worst-case error pattern in the parity section based on the actual error pattern detected. The SER assessment predicted will be equal to or better than the output of a real system. To calculate a more exact SER, as opposed to an upper bound, an example such as the one disclosed in FIG. 7 may be used.

FIG. 7 is a block diagram of a second embodiment of a test block 700 according to one or more examples of the present specification. In the example of FIG. 6a, test block 600 essentially assumes that all bits are created equal. However, in a real-world data stream, some bits may be more important than other bits, and failure of bits in a certain location may have greater downstream effects than in other locations. For example, if an unrecoverable error occludes in the header portion of a packet, the entire packet may be lost, while if an error occurs in a data frame portion, only that single data frame may be lost, and may be retransmitted. Thus, test block 700 of FIG. 7 illustrates an example in which Reed-Solomon (RS) encoding is used to compute errors without treating all bits as being “equal.” In test block 700, the actual coding may be performed by the transmitter. In this case, only the data encoder of the error correction scheme (for example RS encoder 708) need be implemented in both the transmit and receive side. A receive side PRBS generator may be initialized through a sync block as before, so that the received RS encoded payload (plus parity headers) received is identical to the locally generated PRBS.

Once identity is detected, the receive side PRBS generator may be locked, and the test may begin. As before, within comparator 704, a reference data stream which is assumed to be “clean” (BER=0) is compared to the input data stream and any errors are detected and recorded in FIFO buffer 716. Errors can be reported out to a test bench and processed as illustrated in FIG. 6a.

Because both the structure and parity section of the code are present in the compared bitstream between input data stream and reference data stream, the error events recorded represent the entire data affected by receiver decision errors, and the postprocessing analysis may account for irrecoverable errors in the parity section as well. This enables a determination of the actual SER, rather than just a worst-case bounding of the SER.

Additional logic required on the SERDES for this scheme conforms to a specific standard FEC system, as defined by IEEE 802.3bj. Other systems may require differing widths, lengths of blocks, etc. Embodiments may include, by way of nonlimiting example:
A FIFO or memory containing DIP times 5440 bits (RS block) or BER count (13 bit).
A FEC block counter 720 (32 bits)
RS encoder 708 synced with PRBS generator 712, to locally generate to the RX the same bitstream received at the output of the RX decision point.
Comparator 704 from SERDES and data from receiver side FEC encoder. Comparator 704 writes to FIFO buffer 716 only FEC blocks that cannot be fixed (for example, in 50 Gb Ethernet over 15 symbol errors in PAM4 or 7 symbol errors in PAM2).

FIG. 8 is a block diagram of a third embodiment of a test block 800, according to one or more examples of the present specification. In the example of test block 800, error events may be recorded and compressed and their locations in the bitstream may be saved, and then reported continuously or periodically to a test bench via a side channel. In this case, it can be assumed that DER is less than M, and the average compression ratio achieved by the compression logic is N:1. Thus, the side channel may require only a rate of fM/N. For example, if F=50 Gb per second, M equals 1×10⁻⁴, and N=5, then the side channel rate need be only 1 Mb per second.

Assuming a typical uncompressed error rate (for example, location in PRBS 31 plus error event) is of 100 bits, then a simple low-speed IO channel out of the chip transmitting at 500 KBPS*100=100 MBPS (500 Kb per second times 100 equals 100 Mb per second) could be utilized to transmit the entire error event information to the test bench for external error processing indefinitely. Note that this method works on both PRBS and FEC encoded data, as illustrated in FIGS. 6a and 7 above.

For example, test block 800 may include a PRBS generator 816, a PRBS comparator 812, and a PRBS wraparound counter 818, similar to the set up in FIG. 6a. However, rather than storing data to a FIFO buffer, test block 800 pushes data out to a compressor 804, which may include a much smaller buffer in some embodiments. Compressor 804 compresses the data, and reports errors out to the test bench via a low bandwidth interface in near real-time, or periodically as appropriate to the embodiment.

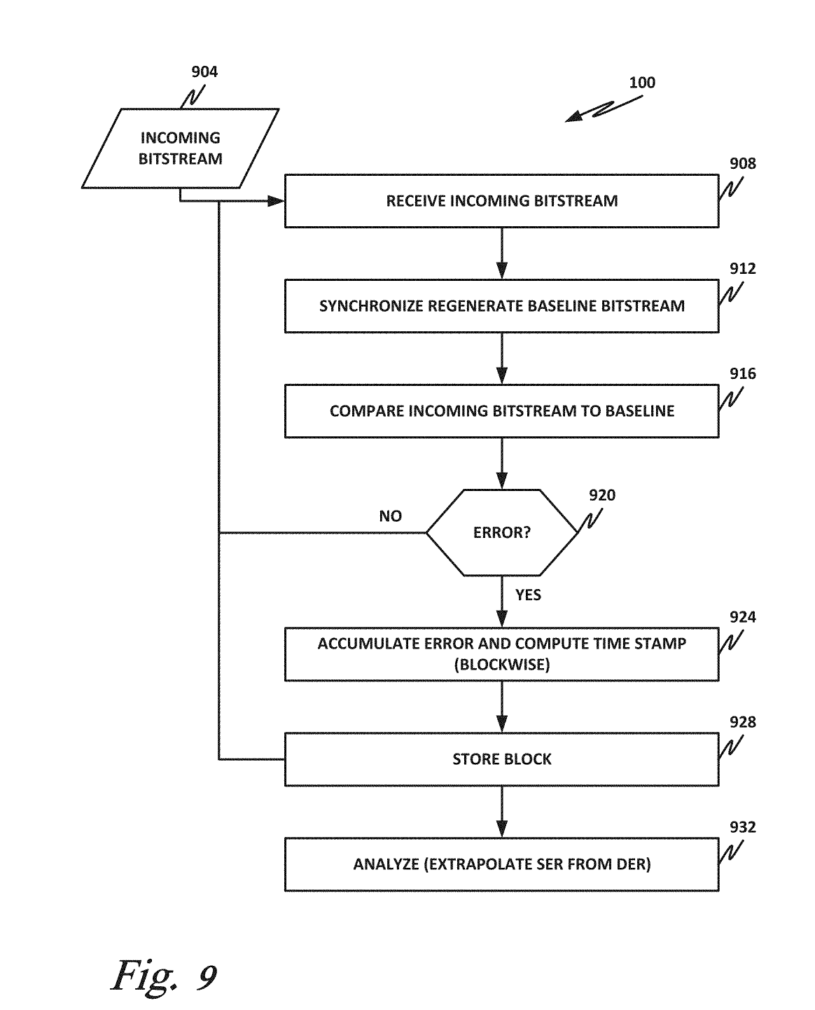

FIG. 9 is a flowchart of a method 900 of predicting a BER, according to one or more examples of the present specification.

In block 908, a test block receives an incoming bitstream 904, for example from a SERDES.

In block 912, the test block synchronizes its local PRBS generator with the input data stream and generates a baseline bitstream for comparison.

In block 916, a comparator compares the incoming bitstream 904 to the baseline bitstream generated in block 912.

In decision block 920, if there are no errors detected, then a new packet, frame, or burst of bits may be received from incoming bitstream 904, and comparison may continue.

Returning to block 920, if an error is detected, then in block 924, the test block accumulates the error, and computes a timestamp. This is illustrated, for example, in FIG. 6b. This can include computing and calculating information for reproducing the location of the error in the bitstream, such as by using a PRBS wraparound counter, and prepending to the error N clean bits. The error is stored in a blockwise fashion.

In block 928, the error is stored, such as to a FIFO buffer, or sent to a compressor.

In block 932, a test bench may analyze the error data, whereby the SER may be mathematically extrapolated from the recorded DER, such as by providing a worst-case bound of the SER, or by a computing the actual SER.

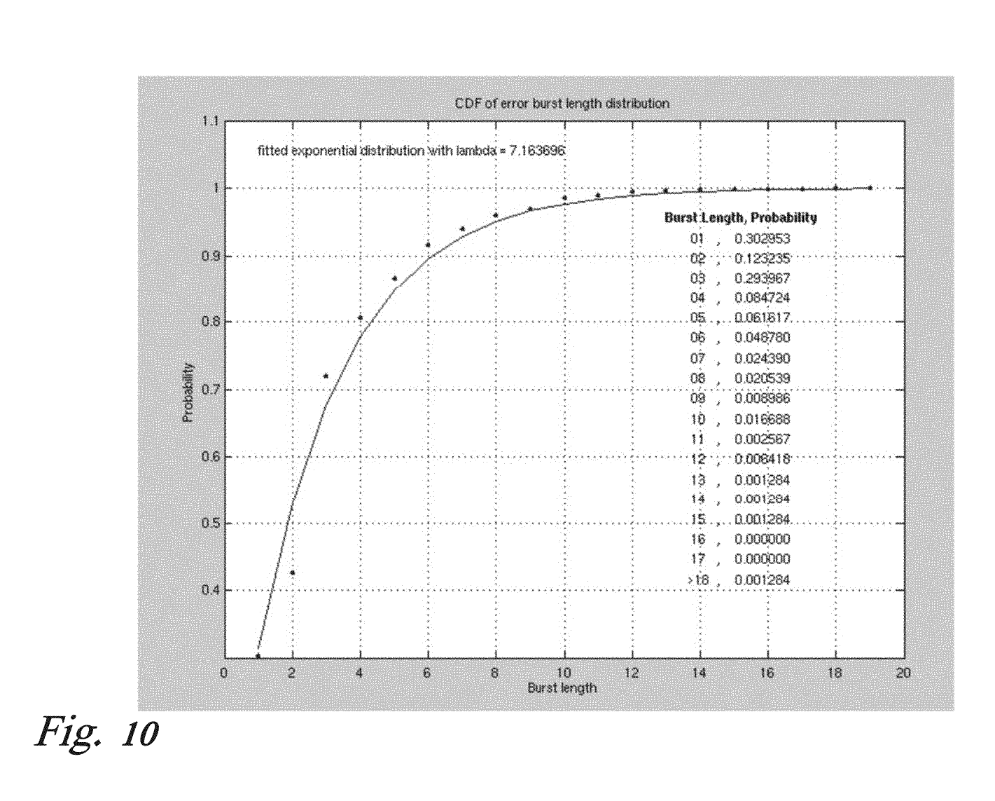

FIG. 10 illustrates an experimental example of an error burst length distribution channel definition format (CDF), according to one or more examples of the present specification. In this embodiment, individual probabilities of specific error bursts were determined. This was for a PHY with 5 DFE taps and overall BER of approximately 10⁻⁴. The probabilities represent the percentage of length-k error bursts out of the entire error burst distribution. For example, approximately 30.3% of the error bursts are length 1. FIG. 10 illustrates that a fit of the distribution of burst lengths provides an exponential distribution of A=7.1637. Once the distribution has been identified and its parameters estimated, it can be used with other postprocessing steps to calculate the BER (SER) at the error correction scheme output.

The foregoing outlines features of one or more embodiments of the subject matter disclosed herein. These embodiments are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present specification.

The PHOSITA will appreciate that they may readily use the present disclosure as a basis for designing or modifying other processes, structures, or variations for carrying out the same purposes and/or achieving the same advantages of the embodiments introduced herein. The PHOSITA will also recognize that such equivalent constructions do not depart from the spirit and scope of the present disclosure, and that they may make various changes, substitutions, and alterations herein without departing from the spirit and scope of the present disclosure.

In the foregoing description, certain aspects of some or all embodiments are described in greater detail than is strictly necessary for practicing the appended claims. These details are provided by way of non-limiting example only, for the purpose of providing context and illustration of the disclosed embodiments. Such details should not be understood to be required, and should not be “read into” the claims as limitations. The phrase may refer to “an embodiment” or “embodiments.” These phrases, and any other references to embodiments, should be understood broadly to refer to any combination of one or more embodiments. Furthermore, the several features disclosed in a particular “embodiment” could just as well be spread across multiple embodiments. For example, if features 1 and 2 are disclosed in “an embodiment,” embodiment A may have feature 1 but lack feature 2, while embodiment B may have feature 2 but lack feature 1.

This specification may provide illustrations in a block diagram format, wherein certain features are disclosed in separate blocks. These should be understood broadly to disclose how various features interoperate, but are not intended to imply that those features must necessarily be embodied in separate hardware or software. Furthermore, where a single block discloses more than one feature in the same block, those features need not necessarily be embodied in the same hardware and/or software. For example, a computer “memory” could in some circumstances be distributed or mapped between multiple levels of cache or local memory, main memory, battery-backed volatile memory, and various forms of persistent memory such as a hard disk, storage server, optical disk, tape drive, or similar. In certain embodiments, some of the components may be omitted or consolidated. In a general sense, the arrangements depicted in the FIGURES may be more logical in their representations, whereas a physical architecture may include various permutations, combinations, and/or hybrids of these elements. Countless possible design configurations can be used to achieve the operational objectives outlined herein. Accordingly, the associated infrastructure has a myriad of substitute arrangements, design choices, device possibilities, hardware configurations, software implementations, and equipment options.

References may be made herein to a computer-readable medium, which may be a tangible and non-transitory computer-readable medium. As used in this specification and throughout the claims, a “computer-readable medium” should be understood to include one or more computer-readable mediums of the same or different types. A computer-readable medium may include, by way of non-limiting example, an optical drive (e.g., CD/DVD/Blu-Ray), a hard drive, a solid-state drive, a flash memory, or other non-volatile medium. A computer-readable medium could also include a medium such as a read-only memory (ROM), an FPGA or ASIC configured to carry out the desired instructions, stored instructions for programming an FPGA or ASIC to carry out the desired instructions, an intellectual property (IP) block that can be integrated in hardware into other circuits, or instructions encoded directly into hardware or microcode on a processor such as a microprocessor, digital signal processor (DSP), microcontroller, or in any other suitable component, device, element, or object where appropriate and based on particular needs. A nontransitory storage medium herein is expressly intended to include any nontransitory special-purpose or programmable hardware configured to provide the disclosed operations, or to cause a processor to perform the disclosed operations.

Various elements may be “communicatively,” “electrically,” “mechanically,” or otherwise “coupled” to one another throughout this specification and the claims. Such coupling may be a direct, point-to-point coupling, or may include intermediary devices. For example, two devices may be communicatively coupled to one another via a controller that facilitates the communication. Devices may be electrically coupled to one another via intermediary devices such as signal boosters, voltage dividers, or buffers. Mechanically-coupled devices may be indirectly mechanically coupled.

Any “module” or “engine” disclosed herein may refer to or include software, a software stack, a combination of hardware, firmware, and/or software, a circuit configured to carry out the function of the engine or module, or any computer-readable medium as disclosed above. Such modules or engines may, in appropriate circumstances, be provided on or in conjunction with a hardware platform, which may include hardware compute resources such as a processor, memory, storage, interconnects, networks and network interfaces, accelerators, or other suitable hardware. Such a hardware platform may be provided as a single monolithic device (e.g., in a PC form factor), or with some or part of the function being distributed (e.g., a “composite node” in a high-end data center, where compute, memory, storage, and other resources may be dynamically allocated and need not be local to one another).

There may be disclosed herein flow charts, signal flow diagram, or other illustrations showing operations being performed in a particular order. Unless otherwise expressly noted, or unless required in a particular context, the order should be understood to be a non-limiting example only. Furthermore, in cases where one operation is shown to follow another, other intervening operations may also occur, which may be related or unrelated. Some operations may also be performed simultaneously or in parallel. In cases where an operation is said to be “based on” or “according to” another item or operation, this should be understood to imply that the operation is based at least partly on or according at least partly to the other item or operation. This should not be construed to imply that the operation is based solely or exclusively on, or solely or exclusively according to the item or operation.

All or part of any hardware element disclosed herein may readily be provided in a system-on-a-chip (SoC), including a central processing unit (CPU) package. An SoC represents an integrated circuit (IC) that integrates components of a computer or other electronic system into a single chip. Thus, for example, client devices or server devices may be provided, in whole or in part, in an SoC. The SoC may contain digital, analog, mixed-signal, and radio frequency functions, all of which may be provided on a single chip substrate. Other embodiments may include a multichip module (MCM), with a plurality of chips located within a single electronic package and configured to interact closely with each other through the electronic package.

In a general sense, any suitably-configured circuit or processor can execute any type of instructions associated with the data to achieve the operations detailed herein. Any processor disclosed herein could transform an element or an article (for example, data) from one state or thing to another state or thing. Furthermore, the information being tracked, sent, received, or stored in a processor could be provided in any database, register, table, cache, queue, control list, or storage structure, based on particular needs and implementations, all of which could be referenced in any suitable timeframe. Any of the memory or storage elements disclosed herein, should be construed as being encompassed within the broad terms “memory” and “storage,” as appropriate.

Computer program logic implementing all or part of the functionality described herein is embodied in various forms, including, but in no way limited to, a source code form, a computer executable form, machine instructions or microcode, programmable hardware, and various intermediate forms (for example, forms generated by an assembler, compiler, linker, or locator). In an example, source code includes a series of computer program instructions implemented in various programming languages, such as an object code, an assembly language, or a high-level language such as OpenCL, FORTRAN, C, C++, JAVA, or HTML for use with various operating systems or operating environments, or in hardware description languages such as Spice, Verilog, and VHDL. The source code may define and use various data structures and communication messages. The source code may be in a computer executable form (e.g., via an interpreter), or the source code may be converted (e.g., via a translator, assembler, or compiler) into a computer executable form, or converted to an intermediate form such as byte code. Where appropriate, any of the foregoing may be used to build or describe appropriate discrete or integrated circuits, whether sequential, combinatorial, state machines, or otherwise.

In one example embodiment, any number of electrical circuits of the FIGURES may be implemented on a board of an associated electronic device. The board can be a general circuit board that can hold various components of the internal electronic system of the electronic device and, further, provide connectors for other peripherals. Any suitable processor and memory can be suitably coupled to the board based on particular configuration needs, processing demands, and computing designs. Note that with the numerous examples provided herein, interaction may be described in terms of two, three, four, or more electrical components. However, this has been done for purposes of clarity and example only. It should be appreciated that the system can be consolidated or reconfigured in any suitable manner. Along similar design alternatives, any of the illustrated components, modules, and elements of the FIGURES may be combined in various possible configurations, all of which are within the broad scope of this specification.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 (pre-AIA) or paragraph (f) of the same section (post-AIA), as it exists on the date of the filing hereof unless the words “means for” or “steps for” are specifically used in the particular claims; and (b) does not intend, by any statement in the specification, to limit this disclosure in any way that is not otherwise expressly reflected in the appended claims.

### EXAMPLE IMPLEMENTATIONS

The following examples are provided by way of illustration.

Example 1 includes an apparatus to derive a symbol error rate (SER) of an interconnect under test from a detector error rate (DER) of the interconnect, comprising: an error storage buffer; an input interface to communicatively couple to a serializer-deserializer (SERDES) at a physical (PHY) level of an interconnect and to receive an input bitstream via the PHY level of the interconnect; a bitstream regenerator; a synchronization interface to receive synchronization data for the bitstream regenerator to reconstruct a clean reference bitstream; and a comparator to: compare the input bitstream to the clean reference bitstream; identify an error in the input bitstream comprising identifying a difference between the clean reference bitstream and the input bitstream; and store an error record in the error storage buffer, the error record comprising the error prepended by a plurality of clean bits to enable an analyzer to locate the error within the input data stream and construct a DER therefrom.

Example 2 includes the apparatus of example 1, further comprising an output interface to export data from the error storage buffer to the analyzer.

Example 3 includes the apparatus of example 2, wherein the output interface is a sideband interconnect with a low speed relative to an operational speed of the interconnect under test.

Example 4 includes the apparatus of example 3, wherein the error storage buffer comprises a compressor, and wherein the comparator is to export the data continuously or periodically to the analyzer.

Example 5 includes the apparatus of example 1, wherein the bitstream regenerator is a pseudorandom bit sequence (PRBS) generator.

Example 6 includes the apparatus of example 5, wherein the synchronization data comprise N bits to synchronize the PRBS generator with a PRBS-N stream.

Example 7 includes the apparatus of example 5, wherein the synchronization data comprise a PRBS wraparound counter.

Example 8 includes the apparatus of example 1, wherein the error record further comprises a PRBS wraparound counter.

Example 9 includes the apparatus of example 1, wherein the bitstream regenerator comprises a Reed-Solomon encoder to encode the reference bitstream with payload and header data.

Example 10 includes a post processor, comprising: the apparatus of any of examples 1-7; and a test bench to provide the analyzer, the test bench comprising: an error record interface to receive error records from the apparatus; a DER constructor to construct a DER for the interconnect under test from the error records; and a SER constructor to predict a SER from the DER.

Example 11 includes the post processor of example 10, wherein predicting the SER comprises predicting an upper bound of the SER.

Example 12 includes the post processor of example 10, wherein predicting the SER comprises predicting a value of the SER.

Example 13 includes one or more tangible, non-transitory computer-readable mediums having stored thereon instructions to derive a symbol error rate (SER) of an interconnect under test from a detector error rate (DER) of the interconnect, the instructions to instruct a hardware platform to: communicatively couple to a serializer-deserializer (SERDES) at a physical (PHY) level of an interconnect and to receive an input bitstream via the PHY level of the interconnect; receive synchronization data for a bitstream regenerator and instruct the bitstream regenerator to reconstruct a clean reference bitstream; compare the input bitstream to the clean reference bitstream; identify an error in the input bitstream comprising identifying a difference between the clean reference bitstream and the input bitstream; and store an error record in an error storage buffer, the error record comprising the error prepended by a plurality of clean bits to enable an analyzer to locate the error within the input data stream and construct a DER therefrom.

Example 14 includes the one or more tangible, non-transitory computer-readable mediums of example 13, wherein the instructions are further to instruct the hardware platform to export data from the error storage buffer to the analyzer via an output interface.

Example 15 includes the one or more tangible, non-transitory computer-readable mediums of example 14, wherein the output interface is a sideband interconnect with a low speed relative to an operational speed of the interconnect under test.

Example 16 includes the one or more tangible, non-transitory computer-readable mediums of example 15, wherein the instructions are further to instruct the processor to compress the error record and to export the data continuously or periodically to the analyzer.

Example 17 includes the one or more tangible, non-transitory computer-readable mediums of example 13, wherein the bitstream regenerator is a pseudorandom bit sequence (PRBS) generator.

Example 18 includes the one or more tangible, non-transitory computer-readable mediums of example 17, wherein the synchronization data comprise N bits to synchronize the PRBS generator with a PRBS-N stream.

Example 19 includes the one or more tangible, non-transitory computer-readable mediums of example 17, wherein the synchronization data comprise a PRBS wraparound counter.

Example 20 includes the one or more tangible, non-transitory computer-readable mediums of example 13, wherein the error record further comprises a PRBS wraparound counter.

Example 21 includes the one or more tangible, non-transitory computer-readable mediums of example 13, wherein the bitstream regenerator comprises a Reed-Solomon encoder to encode the reference bitstream with payload and header data.

Example 22 includes the one or more tangible, non-transitory computer-readable mediums of any of examples 13-21, wherein the instructions are further to: receive a plurality of error records; construct a DER for the interconnect under test from the plurality of error records; and predict a SER from the DER.

Example 23 includes the one or more tangible, non-transitory computer-readable mediums of example 22, wherein predicting the SER comprises predicting an upper bound of the SER.

Example 24 includes the one or more tangible, non-transitory computer-readable mediums of example 23, wherein predicting the SER comprises predicting a value of the SER.

Example 25 includes a method of deriving a symbol error rate (SER) of an interconnect under test from a detector error rate (DER) of the interconnect, comprising: communicatively coupling to a serializer-deserializer (SERDES) at a physical (PHY) level of an interconnect and to receive an input bitstream via the PHY level of the interconnect; receiving synchronization data for a bitstream regenerator and instructing the bitstream regenerator to reconstruct a clean reference bitstream; comparing the input bitstream to the clean reference bitstream; identify an error in the input bitstream comprising identifying a difference between the clean reference bitstream and the input bitstream; and store an error record in an error storage buffer, the error record comprising the error prepended by a plurality of clean bits to enable an analyzer to locate the error within the input data stream and construct a DER therefrom.

Example 26 includes the method of example 25, further comprising exporting data from the error storage buffer to the analyzer via an output interface.

Example 27 includes the method of example 26, wherein the output interface is a sideband interconnect with a low speed relative to an operational speed of the interconnect under test.

Example 28 includes the method of example 26, further comprising compressing the error record and to exporting the data continuously or periodically to the analyzer.

Example 29 includes the method of example 25, wherein the bitstream regenerator is a pseudorandom bit sequence (PRBS) generator.

Example 30 includes the method of example 29, wherein the synchronization data comprise N bits to synchronize the PRBS generator with a PRBS-N stream.

Example 31 includes the method of example 29, wherein the synchronization data comprise a PRBS wraparound counter.

Example 32 includes the method of example 25, wherein the error record further comprises a PRBS wraparound counter.

Example 33 includes the method of example 25, wherein the bitstream regenerator comprises a Reed-Solomon encoder to encode the reference bitstream with payload and header data.

Example 34 includes the method of any of examples 25-33, further comprising: receiving a plurality of error records; constructing a DER for the interconnect under test from the plurality of error records; and predicting a SER from the DER.

Example 35 includes the method of example 34, wherein predicting the SER comprises predicting an upper bound of the SER.

Example 36 includes the method of example 34, wherein predicting the SER comprises predicting a value of the SER.

Example 37 includes an apparatus comprising means for performing the method of any of examples 25-36.

Example 38 includes the apparatus of example 37, wherein the means for performing the method comprises a processor and a memory.

Example 39 includes the apparatus of example 37, wherein the memory comprises machine-readable instructions, that when executed cause the apparatus to perform the method of any of examples 25-36.

Example 40 includes the apparatus of any of examples 37-39, wherein the apparatus is a computing system.

Example 41 includes at least one computer readable medium comprising instructions that, when executed, implement a method or realize an apparatus as illustrated in any of examples 25-40.

What is claimed is:

1. An apparatus to derive a symbol error rate (SER) of an interconnect under test from a detector error rate (DER) of the interconnect, comprising:
an error storage buffer;
an input interface to communicatively couple to a serializer-deserializer (SERDES) at a physical (PHY) level of an interconnect and to receive an input bitstream via the PHY level of the interconnect;
a bitstream regenerator;
a synchronization interface to receive synchronization data for the bitstream regenerator to reconstruct a clean reference bitstream; and
a comparator to:
compare the input bitstream to the clean reference bitstream;
identify an error in the input bitstream comprising identifying a difference between the clean reference bitstream and the input bitstream; and
store an error record in the error storage buffer, the error record comprising the error prepended by a plurality of clean bits to enable an analyzer to locate the error within the input data stream and construct a DER therefrom.

2. The apparatus of claim 1, further comprising an output interface to export data from the error storage buffer to the analyzer.

3. The apparatus of claim 2, wherein the output interface is a sideband interconnect with a low speed relative to an operational speed of the interconnect under test.

4. The apparatus of claim 3, wherein the error storage buffer comprises a compressor, and wherein the comparator is to export the data continuously or periodically to the analyzer.

5. The apparatus of claim 1, wherein the bitstream regenerator is a pseudorandom bit sequence (PRBS) generator.

6. The apparatus of claim 5, wherein the synchronization data comprise N bits to synchronize the PRBS generator with a PRBS-N stream.

7. The apparatus of claim 5, wherein the synchronization data comprise a PRBS wraparound counter.

8. The apparatus of claim 1, wherein the error record further comprises a PRBS wraparound counter.

9. The apparatus of claim 1, wherein the bitstream regenerator comprises a Reed-Solomon encoder to encode the reference bitstream with payload and header data.

10. A post processor, comprising:
the apparatus of claim 1; and
a test bench to provide the analyzer, the test bench comprising:
an error record interface to receive error records from the apparatus;
a DER constructor to construct a DER for the interconnect under test from the error records; and
a SER constructor to predict a SER from the DER.

11. The post processor of claim 10, wherein predicting the SER comprises predicting an upper bound of the SER.

12. The post processor of claim 10, wherein predicting the SER comprises predicting a value of the SER.

13. One or more tangible, non-transitory computer-readable mediums having stored thereon instructions to derive a symbol error rate (SER) of an interconnect under test from a detector error rate (DER) of the interconnect, the instructions to instruct a hardware platform to:
communicatively couple to a serializer-deserializer (SERDES) at a physical (PHY) level of an interconnect and to receive an input bitstream via the PHY level of the interconnect;
receive synchronization data for a bitstream regenerator and instruct the bitstream regenerator to reconstruct a clean reference bitstream;
compare the input bitstream to the clean reference bitstream;
identify an error in the input bitstream comprising identifying a difference between the clean reference bitstream and the input bitstream; and
store an error record in an error storage buffer, the error record comprising the error prepended by a plurality of clean bits to enable an analyzer to locate the error within the input data stream and construct a DER therefrom.

14. The one or more tangible, non-transitory computer-readable mediums of claim 13, wherein the instructions are further to instruct the hardware platform to export data from the error storage buffer to the analyzer via an output interface.

15. The one or more tangible, non-transitory computer-readable mediums of claim 14, wherein the output interface is a sideband interconnect with a low speed relative to an operational speed of the interconnect under test.

16. The one or more tangible, non-transitory computer-readable mediums of claim 15, wherein the instructions are further to instruct the processor to compress the error record and to export the data continuously or periodically to the analyzer.

17. The one or more tangible, non-transitory computer-readable mediums of claim 13, wherein the bitstream regenerator is a pseudorandom bit sequence (PRBS) generator.

18. The one or more tangible, non-transitory computer-readable mediums of claim 17, wherein the synchronization data comprise N bits to synchronize the PRBS generator with a PRBS-N stream.

19. The one or more tangible, non-transitory computer-readable mediums of claim 17, wherein the synchronization data comprise a PRBS wraparound counter.

20. The one or more tangible, non-transitory computer-readable mediums of claim 13, wherein the error record further comprises a PRBS wraparound counter.

21. The one or more tangible, non-transitory computer-readable mediums of claim 13, wherein the bitstream regenerator comprises a Reed-Solomon encoder to encode the reference bitstream with payload and header data.

22. The one or more tangible, non-transitory computer-readable mediums of claim 13, wherein the instructions are further to:
receive a plurality of error records;
construct a DER for the interconnect under test from the plurality of error records; and
predict a SER from the DER.

23. The one or more tangible, non-transitory computer-readable mediums of claim 22, wherein predicting the SER comprises predicting an upper bound of the SER.

24. The one or more tangible, non-transitory computer-readable mediums of claim 23, wherein predicting the SER comprises predicting a value of the SER.

25. A method of deriving a symbol error rate (SER) of an interconnect under test from a detector error rate (DER) of the interconnect, comprising:
communicatively coupling to a serializer-deserializer (SERDES) at a physical (PHY) level of an interconnect and to receive an input bitstream via the PHY level of the interconnect;
receiving synchronization data for a bitstream regenerator and instructing the bitstream regenerator to reconstruct a clean reference bitstream;
comparing the input bitstream to the clean reference bitstream;
identify an error in the input bitstream comprising identifying a difference between the clean reference bitstream and the input bitstream; and
store an error record in an error storage buffer, the error record comprising the error prepended by a plurality of clean bits to enable an analyzer to locate the error within the input data stream and construct a DER therefrom.
